(19) United States
(12) Patent Application Publication
(10) Pub. No.: US 2008/0124890 A1
(43) Pub. Date: May 29, 2008

(54) METHOD FOR FORMING SHALLOW TRENCH ISOLATION STRUCTURE

(75) Inventors: Chih-Yuan Wu, Hsinchu (TW); Hsin-Huei Chen, Hsinchu (TW); Shih-Keng Cho, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: MACRONIX INTERNATIONAL CO., LTD., Hsinchu (TW)

(21) Appl. No.: 11/426,583

(22) Filed: Jun. 27, 2006

(51) Int. Cl. H01L 21/76

(52) U.S. Cl. 438/425; 257/E21.546

(57) ABSTRACT

A method for forming a shallow trench isolation structure is described. A trench is formed in a substrate, and then a liner layer is formed in the trench. A portion of the liner layer around the top corner of the trench is removed, and then the trench is filled with an insulating material.

### BACKGROUND OF THE INVENTION

1. Field of the Invention

The present invention relates to a semiconductor process. More particularly, the present invention relates to a method for forming a shallow trench isolation (STI) structure on a semiconductor wafer.

2. Description of the Related Art

STI structures are widely used as isolation structures of semiconductor devices for providing excellent isolation effect, but the devices separated by STI structures often suffer from lattice dislocations causing remarkable current leakage.

A method frequently used to reduce dislocations is to form a silicon nitride (SiN) liner layer in the trench, but the liner layer adversely causes more gate oxide thinning at the top corner of the STI trench for the clean recipe of cleaning the pad oxide is difficult to control the STI oxide loss near the top corner of the trench when there is liner nitride near the top corner. The pad oxide is formed on the substrate before the mask layer for defining the STI trench is formed, mainly serving as a stress buffer for the mask layer.

### SUMMARY OF THE INVENTION

In view of the foregoing, this invention provides a method for forming an STI structure without the above gate dielectric thinning problem.

The method for forming an STI structure of this invention is described below. A trench is formed in a substrate, and then a liner layer is formed in the trench. A portion of the liner layer around a top corner of the trench is removed, and then the trench is filled with an insulating material.

In the above method, removing the portion of the liner layer may be done by first forming in the trench a screen layer that exposes the portion of the liner layer and then etching away the portion of the liner layer using the screen layer as a mask. In some embodiments, the screen layer includes a suitable insulating material and can be kept after use to be a part of the STI structure. In some embodiments, the screen layer is not suitable to be a part of the STI structure and is removed after use. Such a screen layer may include a photoresist material.

Moreover, in an embodiment where pad oxide is formed prior to a mask layer for defining the trench and cleaned after the mask layer is removed and where the insulating material is SiO, the STI oxide loss near the top corner of the trench is easier to control in cleaning the pad oxide because the portion of the liner layer around the top corner of the trench has been removed, so that the gate dielectric thinning problem is improved.

It is to be understood that the foregoing general description and the following detailed description are exemplary, and are intended to provide further explanation of the invention as claimed.

### BRIEF DESCRIPTION OF THE DRAWINGS

FIGS. 1A-1C illustrate, in a cross-sectional view, a process flow of forming an STI structure according to an embodiment of this invention.

FIGS. 2A-2C illustrate, in a cross-sectional view, a process flow of forming an STI structure according to another embodiment of this invention.

### DESCRIPTION OF THE PREFERRED EMBODIMENTS

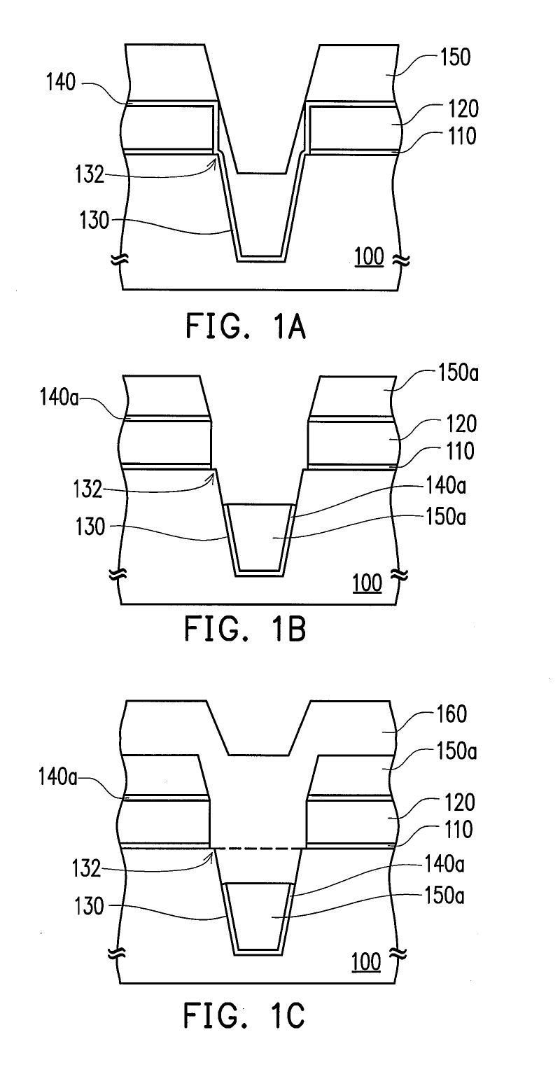

The process flow of forming an STI structure according to an embodiment of this invention is described below in reference of FIGS. 1A-1C, wherein the screen layer includes a suitable insulating material and can be kept as a part of the STI structure.

Referring to FIG. 1A, a substrate 100, such as a single-crystal silicon substrate, is provided, and then a patterned mask layer 120 is formed over the substrate 100, wherein the material of the patterned mask layer 120 may be SiN. Pad oxide 110 is preferably formed, possibly through CVD, on the substrate 100 before the mask layer is formed and patterned, while the etching for forming the patterned mask layer 120 is continued after the mask layer patterning to pattern the pad oxide 110 using the same photoresist pattern (not shown) as a mask.

Then, the substrate 100 is etched using the patterned mask layer 120 as a mask to form a trench 130 in the substrate 100, wherein the trench 130 may have a tapered shape for reducing the stress. A liner layer 140 is formed on the patterned mask layer 120, in the trench 130 and around the top corner 132 of the trench 130, wherein the material of the liner layer 140 may be silicon nitride. An insulating layer 150 as a layer of screen material is formed over the substrate 100, filling in the trench 130 and covering the liner layer 140. The insulating layer 150 may include silicon oxide, which is preferably formed with high-density plasma chemical vapor deposition (HDP-CVD) especially when the process linewidth is small.

Referring to FIG. 1B, the insulating layer 150 is etched until a portion of the liner layer 140 around the top corner 132 of the trench 130 is exposed, so that the remaining insulating layer 150a is partially over the mask layer 120 and partially in the trench 130, wherein the etching may be isotropic etching or anisotropic etching. The portion of the remaining insulating layer 150a in the trench 130 acts as a screen layer for the liner layer 140a to be kept and also as a part of the STI structure to be formed later. Then, the portion of the liner layer 140 around the top corner 132 of the trench 130 exposed by the remaining insulating layer 150a is removed. The exposed liner layer 140 can be removed with phosphoric acid if including SiN.

Referring to FIG. 1C, another insulating layer 160 is formed over the substrate 100 filling up the trench 130. The material of the layer 160 may be the same as that of the insulating layer 150, i.e., SiO, which is preferably formed with HDP-CVD when the process linewidth is small. A potion of the insulating layer 160 outside the trench 130, the remaining insulating layer 150a on the mask layer 120 and the mask layer 120 are then removed, possibly with chemical mechanical polishing (CMP) or the combination of CMP and etching. After that, the pad oxide 110 is cleaned/removed to finish the fabrication of the STI structure, wherein the loss of the insulating layer 160 near the top corner 132 of the trench 130 can be controlled easily for the portion of the liner layer 140 therearound has been removed. Thereby, the gate dielectric thinning problem can be improved in later process. In addition, the insulating layer 160 is partially removed approximately down to the level indicated by the dashed line with the above process.

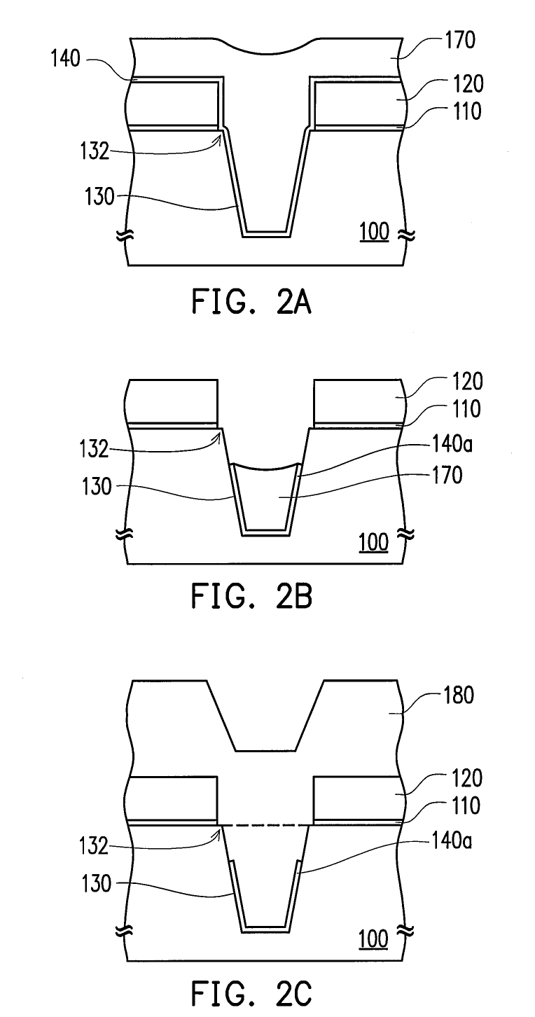

The process flow of forming an STI structure according to another embodiment of this invention is described below in reference of FIGS. 2A-2C, wherein the screen layer is not suitable to serve as a part of the STI structure and is removed after use.

Referring to FIG. 2A, the arrangement of the substrate 100, the pad oxide 110, the patterned mask layer 120, the trench 130 and the liner layer 140 are the same as above, while their forming process and possible materials of the parts 100, 120 and 140 may be the same as above. Then, a screen layer 170 that includes a screen material having a much lower etching selectivity than the liner layer 140 but not being a suitable STI insulating material, such as a photoresist layer, is formed over the substrate 100, filling up the trench 130 and covering the liner layer 140.

Referring to FIG. 2B, the screen layer 170 is etched until a portion of the liner layer 140 around the top corner 132 of the trench 130 is exposed, wherein the etching may be isotropic or anisotropic etching. The exposed portion of the liner layer 140 around the top corner 132 of the trench 130 is then removed.

Referring to FIG. 2C, the remaining screen layer 170 is removed, and then an insulating layer 180 is formed over the substrate 100 filling up the trench 130. The material of the insulating layer 180 may be silicon oxide, which is preferably formed with HDP-CVD especially when the process linewidth is small. Then, a potion of the insulating layer 180 outside the trench 130 and the mask layer 120 are removed, possibly through CMP (and etching). The pad oxide 110 is then cleaned/removed to finish the fabrication of the STI structure, wherein the loss of the insulating layer 160 near the top corner 132 of the trench 130 can be controlled easily because the portion of the liner layer 140 therearound has been removed. Thereby, the gate dielectric thinning problem can be improved in later process. In addition, the insulating layer 180 is partially removed approximately down to the level indicated by the dashed line with the above process.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1-10. (canceled)

11. A method for forming a shallow trench isolation (STI) structure, comprising:
forming a patterned in ask layer on a substrate;
etching substrate using the patterned mask layer as a mask to form a trench in the substrate;
forming a liner layer on the patterned mask layer and in the trench;
forming in the trench a screen layer that at least exposes a portion of the liner layer around atop corner of the trench; and removing the portion of the liner layer using the screen layer as a mask;
filling the trench with a first insulating material; and
removing the patterned mask layer.

12. The method of claim 11, further comprising:
forming pad oxide on the substrate before the patterned mask layer is formed;
continuing to pattern the pad oxide after the patterned mask layer is formed; and
cleaning the pad oxide after the patterned mask layer is removed.

13. The method of claim 11, wherein forming the screen layer comprises:
forming a screen material over the substrate covering the liner layer; and
etching the screen material until the portion of the liner layer is exposed.

14. The method of claim 13, wherein the screen material comprises a second insulating material.

15. The method of claim 14, wherein the second insulating material is the same as the first insulating material.

16. The method of claim 14, wherein the second insulating material is silicon oxide.

17. The method of claim 16, wherein the silicon oxide is formed with HDP-CVD.

18. The method of claim 13, further comprising a step of removing the screen layer after the portion of the liner layer is removed but before the trench is filled with the first insulating material.

19. The method of claim 18, wherein the screen material comprises a photoresist st material.

20. The method of claim 11, wherein the liner layer comprises silicon nitride.
